(19) United States
(12) Patent Application Publication
(10) Pub. No.: US 2025/0192754 A1
(43) Pub. Date: Jun. 12, 2025

(54) LOW-POWER SINGLE-PHASE CLOCKED FLIP-FLOP

(71) Applicant: Intel Corporation, Santa Clara, CA (US)

(72) Inventors: Ganesan Iyer, Phoenix, AZ (US); Anupama Ambardar Thaploo, Folsom, CA (US); Ananthakrishnan Ponnileth Rajendran, Rancho Cordova, CA (US); Sunil Nekkanti, Rancho Cordova, CA (US); Amit Agarwal, Hillsboro, OR (US); Steven K. Hsu, Lake Oswego, OR (US); Mai Z. Vang, Rancho Cordova, CA (US)

(21) Appl. No.: 18/534,484

(22) Filed: Dec. 8, 2023

(51) Int. Cl. H03K 3/012; G06F 1/04; H03K 3/037

(52) U.S. Cl. CPC H03K 3/012; G06F 1/04; H03K 3/0375

(57) ABSTRACT

Embodiments herein relate to a flip-flop circuit which uses a single clock signal for both the primary and secondary latches with either a “0” or a “1” being used to write into the primary latch and either a “1” or a “0,” respectively, being used to write into the secondary latch. The flip-flop can retain the data as long as the power supply is available. Additionally, the flip-flop conserves power by disconnecting one or more paths to power or ground automatically based upon the data that is being stored, thus reducing the leakage current during a storage mode of operation.

### FIELD

The present application generally relates to the field of flip-flop circuits.

### BACKGROUND

Flip-flop circuits, also referred to as flip-flops, are basic components of sequential logic circuits in computing devices. A flip-flop can include one or more latches which each store a bit of data in a storage node, where the value of the bit is represented by one of two stable states. A flip-flop also receives a clock signal which indicates when data is to be latched and output. However, reducing the power consumed by flip-flops is a continuing challenge.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 depicts an example true single-phase clock (TSPC) flip-flop circuit 100, in accordance with various embodiments.

FIG. 2A depicts an example flip-flop circuit 200 having reduced power consumption, in accordance with various embodiments.

FIG. 2B depicts a configuration of the flip-flop circuit 200 of FIG. 2A when writing data=0 to the primary latch 240, with a clock CLK=0, in accordance with various embodiments.

FIG. 2C depicts a configuration of the flip-flop circuit 200 of FIG. 2A when writing data=0 to the secondary latch 270, with CLK=1, in accordance with various embodiments.

FIG. 2D depicts a configuration of the flip-flop circuit 200 of FIG. 2A when writing data=1 to the primary latch 240, with CLK=0, in accordance with various embodiments.

FIG. 2E depicts a configuration of the flip-flop circuit 200 of FIG. 2A when writing data=1 to the secondary latch 270, with CLK=1, in accordance with various embodiments.

FIG. 3 depicts an example table explaining the operations in FIGS. 2B-2E, in accordance with various embodiments.

FIG. 4 depicts example waveforms consistent with the flip-flop circuit 200 of FIG. 2A-2E, in accordance with various embodiments.

FIG. 5 depicts an example flip-flop circuit 500 similar to the flip-flop circuit 200 of FIG. 2A but with transistors N9a and N9b instead of N9 in the secondary latch 570, in accordance with various embodiments.

FIG. 6 depicts an example flip-flop circuit 600 similar to the flip-flop circuit 500 of FIG. 5 but with transistors P7a and P7b instead of P13 in the primary latch 640, in accordance with various embodiments.

FIG. 7 depicts an example flip-flop circuit 700 similar to the flip-flop circuit 200 of FIG. 2B but with a transistor N8a added in the secondary latch 770, in accordance with various embodiments.

FIG. 8 illustrates an example of components that may be present in a computing system 850 for implementing the solutions (e.g., operations, processes, methods, and methodologies) described herein.

### DETAILED DESCRIPTION

As mentioned at the outset, various challenges are presented in reducing the power consumed by flip-flops.

A flip-flop is a data storage element. In one approach, a flip-flop is driven by a two-phase clock scheme and includes a primary latch and a secondary latch, where the primary latch registers a data bit at a certain clock phase and the secondary latch registers a data bit at another phase of the clock. This necessitates an additional clock inverter, hence increasing power consumption.

One possible solution is to use a single-phase clock-based flip-flop. These designs can vary in the dynamic and static nature of the storage element. Some true single-phase clock (TSPC) flip-flops try to reduce power consumption by implementing a dynamic design (e.g., using storage without a keeper cell) or by allowing a floating node condition in certain sections of the design. However, a design which does not employ an active storage element needs to have its data refreshed at a certain frequency, resulting in a relatively high-power consumption. Other disadvantages can include higher clock-to-Q delay, where Q represents the output of the flip-flop. For an edge-triggered flip-flop, the clock-to-Q time is the time it takes for the output to be in a stable state after a clock edge occurs.

The solutions provided herein address the above and other disadvantages. In one aspect, a flip-flop is provided which uses a single clock signal for both the primary and secondary latches with either a “0” or a “1” being used to write into the primary latch and either a “1” or a “0,” respectively, being used to write into the secondary latch.

Advantageously, the flip-flop can retain the data as long as the power supply is available. Additionally, the flip-flop conserves power by disconnecting one or more paths to power or ground automatically based upon the data that is being stored, thus reducing the leakage current during a storage mode of operation. Moreover, in one approach, even though a path to power is disconnected, the design does not have a floating node due to a feedback path.

The solutions provide a number of advantages, including reducing power consumption at the unit cell level. Even greater power savings can be achieved when the flip-flop is used repeatedly in a sequence. An example power savings of over 50% with 10% data toggle (a typical graphic chip application) can be achieved.

These and other features will be further apparent in view of the following discussion.

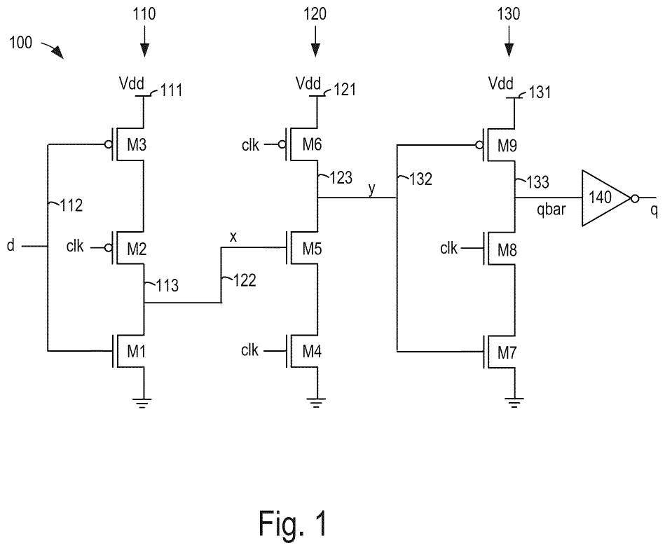

FIG. 1 depicts an example flip-flop circuit 100, in accordance with various embodiments. The flip-flop circuit, or flip-flop for short, includes three branches 110, 120 and 130. The first branch 110 includes a power supply node 111, which receives a power supply yvoltage Vdd, and transistors M1, M2 and M3 connected in series and coupled to ground. M1 is an n-type metal-oxide-semiconductor field-effect transistor (nMOSFET) and M2 and M3 are p-type MOSFETs (pMOSFETs). A data bit d is coupled to the control gates of M1 and M3 via a path 112 and a clock signal (clk) is coupled to a control gate of M2.

The second branch 120 includes a power supply node 121, which receives a voltage Vdd, and transistors M4, M5 and M6 connected in series and coupled to ground. M4 and M5 are nMOSFETs and M6 is a pMOSFET. A node 113 between M1 and M2 is coupled to the control gate of M5 via a path 122 to hold a data bit x. The control gates of M4 and M6 receive clk.

The third branch 130 includes a power supply node 131, which receives a voltage Vdd, and transistors M7, M8 and M9 connected in series and coupled to ground. M7 and M8 are nMOSFETs and M9 is a pMOSFET. A node 123 between M5 and M6 is coupled to the control gates of M7 and M9 via a path 132 to hold a data bit y. The control gate of M8 receives clk. A node 133 between M8 and M9 is coupled to the input of an inverter 140 as qbar (the data output inverted). The inverter in turn provides the data output q.

This is an example implementation of a TSPC flip-flop which has the disadvantage of not being able to retain the data at node y or qbar for an extended period of time due to leakage current which can discharge the node and flip the polarity at the output when this node is not refreshed at a consistent rate.

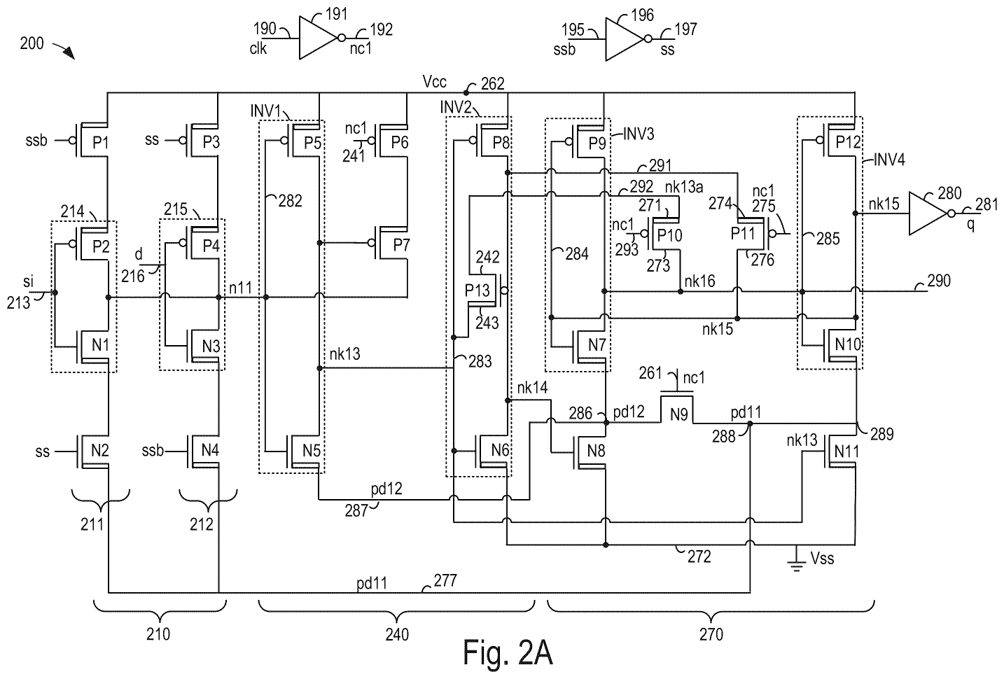

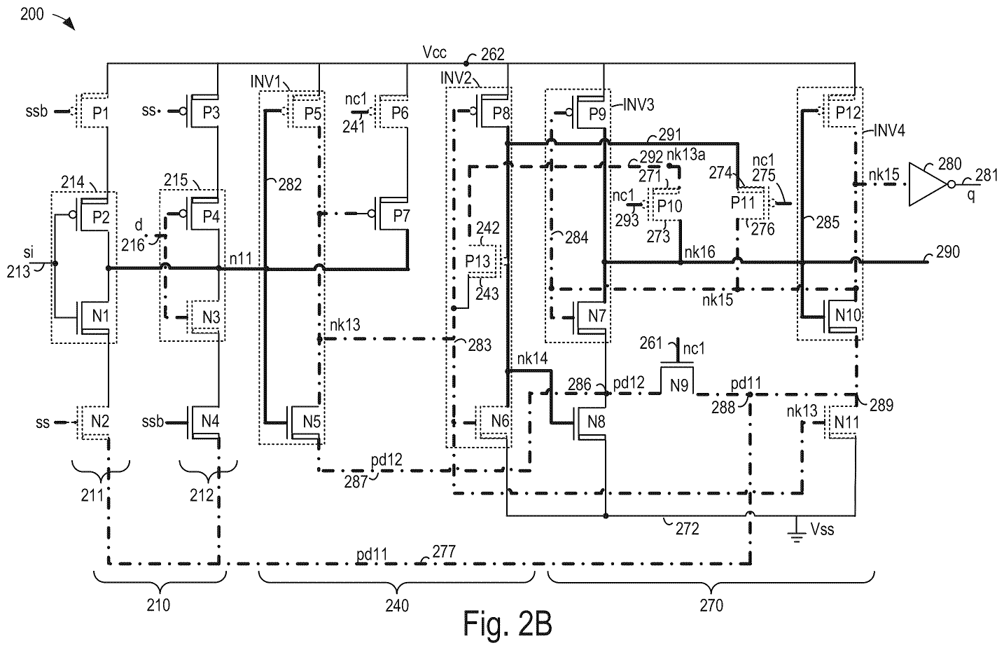

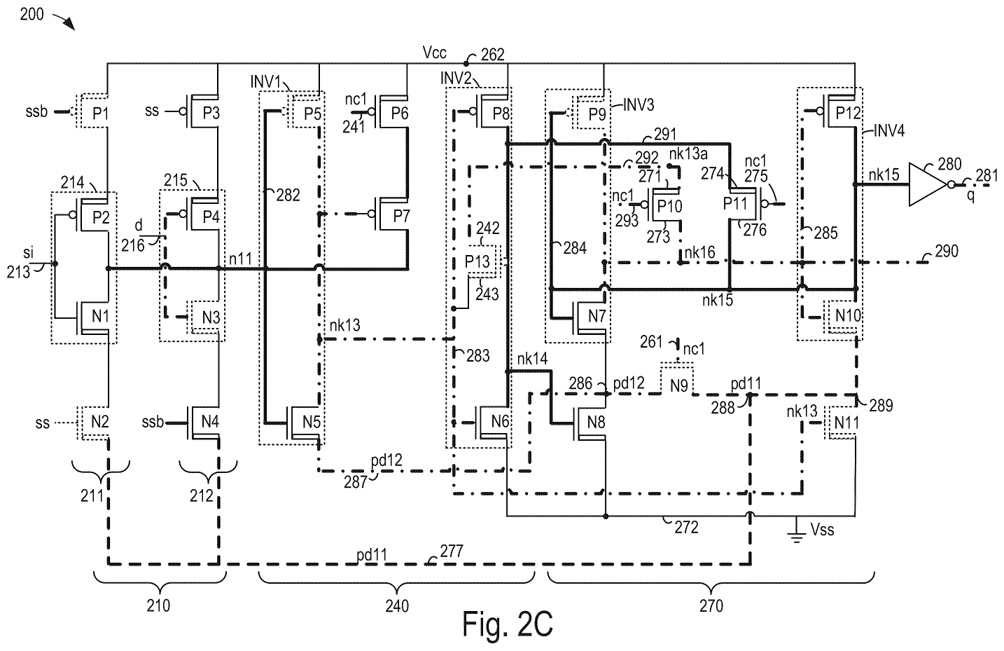

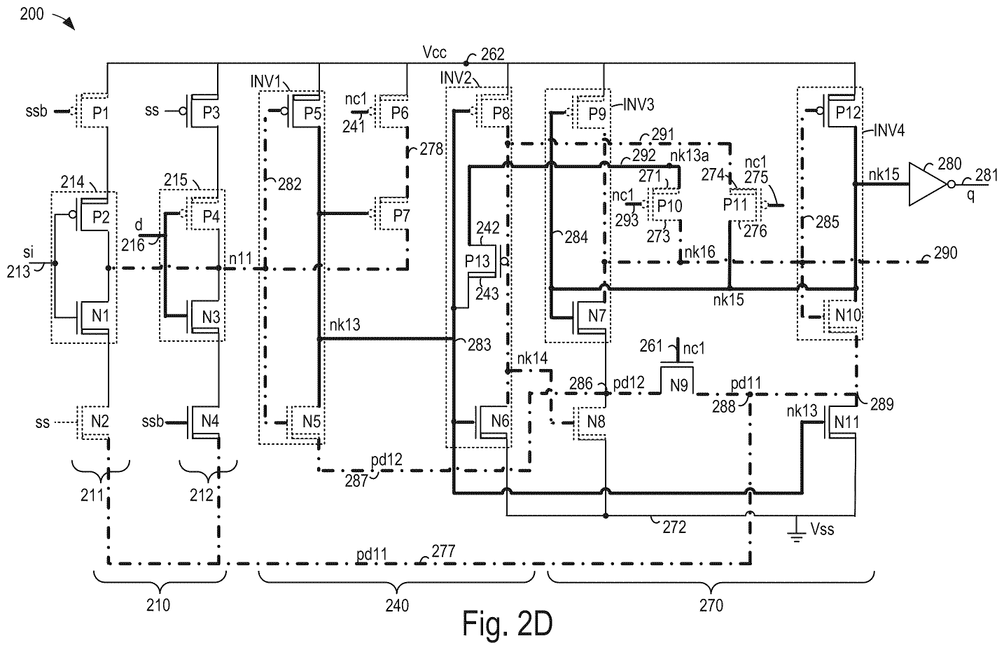

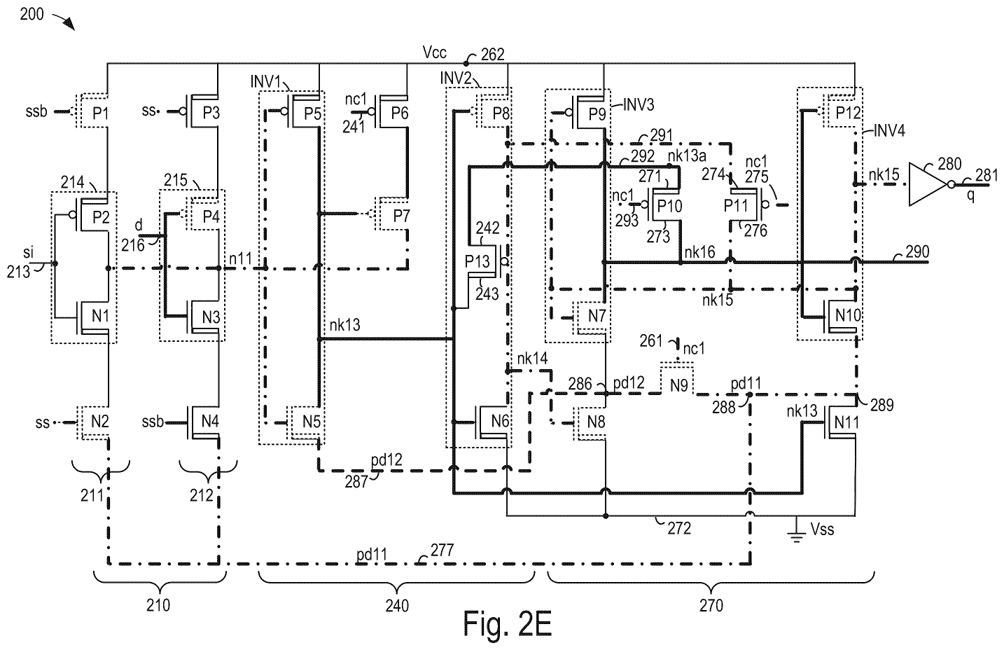

FIG. 2A depicts an example flip-flop circuit 200 having reduced power consumption, in accordance with various embodiments. The flip-flop is a true single-phase clock flip-flop with low power consumption due to a reduced number of clock transistors and with a cross-coupled inverter as a storage element at the secondary stage. An inverter 191 receives a clock signal clk on an input path 190 and outputs an inverse clock signal nc1 on an output path 192. The inverse clock signal is provided to the control gate 241 of a transistor P6, a control gate 275 of a transistor P11, a control gate 293 of a transistor P10 and a control gate 261 of a transistor N9. The transistors which receive nc1 are clocked transistors and the transistors which do not receive nc1 are unclocked transistors.

An inverter 196 receives an inverse scan signal ssb on an input path 195 and outputs a scan signal ss on an output path 197. The inverse scan signal is provided to the control gates of transistors P1 and N4. The scan signal is provided to the control gates of transistors P3 and N2. N4 can be considered to be a pulldown transistor of the multiplexer.

In FIGS. 2A-2E and 5-7, the source end of a transistor is denoted by a double line while the drain end of a transistor is denoted by a single line. Additionally, a pMOSFET is denoted by a circle at the gate of a transistor and labeled starting with a “P” while an nMOSFET is denoted by no circle at the gate of a transistor and labeled starting with an “N.” While MOSFETs are used in these examples, other types of transistors could be used. An nMOSFET is typically conductive or on, such that a channel is formed to couple the source and drain sides of the transistor, when a positive high control gate voltage is applied. A pMOSFET is typically conductive or on when a 0 V or other low voltage control gate voltage is applied.

The flip-flop 200 includes an input multiplexer 210, a primary latch 240 (also referred to as a primary stage) and a secondary latch 270 (also referred to as a secondary stage). The multiplexer provides a data bit on an output node n11 which is either a scan bit si at the node 213 or a data bit d at the node 216. This is an input bit to the primary latch. The multiplexer 210 includes a first path 211 having a series of transistors P1, P2, N1 and N2 and a second path 212 having a series of transistors P3, P4, N3 and N4. In the first path, N1 and P2 with their control gates coupled form an inverter 214. P1 is a stacked transistor between the inverter 214 and a power supply node 262 at a voltage Vcc, and N2 is a stacked transistor between the inverter and a pulldown node 277 also referred to as pd11. In the second path, N3 and P4 with their control gates coupled form an inverter 215. P3 is a stacked transistor between the inverter 215 and the power supply node 262, and N4 is a stacked transistor between the inverter and the pulldown node pd11.

The primary latch 240 includes a first inverter INV1 comprising N5 and P5 and a second inverter INV2 comprising N6 and P8. The data bit at the node n11 is input to INV1 at a node 282 which is coupled to the control gates of P5 and N5. An output of INV1 at a node nk13 is input to INV2 at a node 283 which is coupled to the control gates of P8 and N6. The output of INV1 is high (Vcc) when P5 is on (n11 is low or 0) and low (0 V) when P5 is off (n11 is high or 1).

An output of INV2 at a node nk14 can be stored at a storage node nk15 of the secondary latch via a node 291 when P11 is conductive (on). The node 283 of INV2 is also coupled to P13, which includes a source side 243 and a drain side 242, while nk14 is coupled to the control gate of P13 to control its on/off state. Nk13 is also coupled the control gate of N8. Nk13 can couple the bit at the node 283 to a storage node nk16 via a node 292 when P13 and P10 are conductive. P10 has a control gate 293, a source 271 coupled to the node 292, and a drain 273 coupled to nk16. P11 has a control gate 275, a source 274 coupled to the node 291, and a drain 276 coupled to nk15.

The secondary latch 270 includes a third inverter INV3 comprising N7 and P9 and a fourth inverter INV4 comprising N10 and P12. In INV3, a node 284 with the data from nk15 is coupled to the control gates of N7 and P9. In INV4, a node 285 with the data from nk16 is coupled to the control gates of N10 and P12.

N8 is a stacked transistor of INV3, and is coupled between INV3 and a ground node 272 at Vss. N8 can be considered to be a first grounding transistor as it is coupled to the third inverter and to the ground node 272. Similarly, N11 is a stacked transistor of INV4, and is coupled between INV4 and the ground node 272. N11 can be considered to be a second grounding transistor as it is coupled to the fourth inverter and to the ground node 272. N9 is a clocked bridge transistor which can couple the nodes pd11 or 286 and p12 or 288 when N9 is conductive.

An inverter 280 receives data from node nk15 and outputs data q on an output node 281 as the inverse of nk15. The inverter 280 can be considered to be part of the secondary latch and/or part of an output stage of the flip-flop 200.

The primary latch stores data d in a first storage node (nk13) and an inverse of the data in a second storage node (nk14). The secondary latch stores the data d in a third storage node (nk16) and an inverse of the data in a fourth storage node (nk15).

A node 287 extends from N5 to a node 286. A node 288 is between N9 and a node 289, which is between INV4 and N11. A node 277 extends from the node 288 to N2 and N4.

The inverters INV1-INV4 can be cross-coupled inverters which comprise two transistors of opposite polarity (p-type and n-type) in series, where the control gates of the two transistors are coupled to one another.

Advantageously, the use of nc1, the inverted clock signal, to control the clocked transistors localizes the clock signal within the design. The clock transitions are therefore well-controlled as they are localized. This avoids using the clock signal as an input pin, which can expose the internal clock signal to top level integration.

Additionally, P13 helps to write into the secondary latch even with a high-sigma variance of transistors. The nk13 voltage is used to write both nk16 directly (via P10 and P13) and nk14 indirectly (via INV2). If nk13 is corrupted while writing nk16, the data in nk14 will also be corrupted. However, due to the use of P13, nk13a will not be corrupted during the secondary stage write cycle.

Moreover, the flip-flop does not impose the requirement of a hold violation which can exist in other flip-flops. Instead, the signal from nk16 can be directly output on a path 290 and used in a subsequent flip-flop of the same type without the introduction of any delay element. This is due to the inherent design advantage of using the same clock phase for writing into the primary stage of the subsequent flip-flop.

A further advantage is that the use of the single N9 transistor provides a path to Vss when clk=0 (nc=1) while reducing the clock load by one transistor.

Also, a path comprising P6 and P7 can pull up a voltage at n11 to the power supply voltage Vcc when P6 and P7 are conductive. P6 is conductive when nc1 is low (clk is high) and P7 is conductive when nk13 is low.

The flip-flop can be a D-type flip-flop, for example, as shown here or other type.

The operation of the flip-flop 200 can be understood further in view of FIGS. 2B-2E. In these figures, a non-conductive or off transistor is denoted by a transistor symbol made of dashed lines, and a conductive or on transistor is denoted by a transistor symbol made of solid lines. A high voltage on a node or path is denoted by a heavy solid line, a low voltage on a node or path is denoted by a heavy dot-dash line, and a floating voltage on a node or path is denoted by a heavy dashed line.

FIG. 2B depicts a configuration of the flip-flop circuit 200 of FIG. 2A when writing data=0 to the primary latch 240, with CLK=0, in accordance with various embodiments. Nodes 282, n11, nk14, nk16 and 285 are high, nodes 216, pd11, nk13, 283, nk15, pd11 and pd12 are low and nk13a is floating. In particular, with d=low, n11 is high since P4 passes Vcc to n11. With n11 high, P5 is off and nk13 is set low. Data=0 is thus stored in the primary latch. With nk13 low, P8 is on and nk14 is set high since P8 passes Vcc to nk14. N6 is off with nk13=low. With nk14 high, P13 is off and with nc1=high (clk=low), P10 is off, so that nk13a, which is between these two transistors, has a floating voltage. With nk16 high, P12 is off so that nk15 is low, and q is high.

FIG. 2C depicts a configuration of the flip-flop circuit 200 of FIG. 2A when writing data=0 to the secondary latch 270, with CLK=1, in accordance with various embodiments. After data=0 is written to the primary latch with clk=0, the same data is then written to the secondary latch with clk=1. P6 changes from off to on since nc1 changes from high to low. P9 changes from on to off since nk15 changes from low to high. P10 and P11 change from off to on since nc1 changes from high to low. P12 changes from off to on since nk16 changes from high to low. N10 changes from on to off since nk16 changes from high to low. Nodes pd11, 288 and 289 have a floating voltage since N9-N11 are all floating. This helps maintain data at n11 since n11 does not have a path to ground via N4. The storage node nk16 stores data=0 in the secondary latch since P9 is off, preventing Vcc from being coupled to nk16, and N7 and N8 are on, providing a ground path for nk16. Nk16=nk13a since P10 is on.

FIG. 2D depicts a configuration of the flip-flop circuit 200 of FIG. 2A when writing data=1 to the primary latch 240, with CLK=0, in accordance with various embodiments. Nodes 216, nk13, 283, nk13a, 284 and nk15 are high, nodes n11, 282, nk14, nk16, 285, pd11, pd12, 277 are low and node 278 is floating. In particular, with d=high, n11 is low since P4 is off, and a ground path for n11 is formed via N3, N4, pd11, 277, 288 and N11. With n11 low, P5 is on and nk13 is set high. Data=1 is thus stored in the primary latch. With nk13 high, P8 is off and nk14 is set low since P8 blocks Vcc. nk14 has a ground path via N6. With nk14 low, P13 is on so that nk13a is high (with nk13 high). With nc1=high (clk=low), P10 and P11 are off. With nk16 low, P12 is on so that nk15 is high and q is low.

FIG. 2E depicts a configuration of the flip-flop circuit 200 of FIG. 2A when writing data=1 to the secondary latch 270, with CLK=1, in accordance with various embodiments. After data=1 is written to the primary latch with clk=0, the same data is then written to the secondary latch with clk=1. P6 changes from off to on since nc1 changes from high to low. P8 changes from on to off since nk13 changes from low to high. P9 changes from off to on since nk15 changes from high to low. P10 and P11 change from off to on since nc1 changes from high to low. P12 changes from on to off since nk16 changes from low to high. N10 changes from off to on since nk16 changes from low to high. Node pd12 (including nodes 286 and 287) has a floating voltage since N5 and N9 are floating. This prevents a path to ground for INV1 to help maintain data at nk13. The storage node nk16 stores data=1 in the secondary latch since P9 is on, passing Vcc to nk16, and N7 and N8 are off, blocking a ground path for nk16. Nk16=nk13a since P10 is on.

In FIGS. 2B and 2D, with CLK=0, the primary stage node nk13 is written with data=0. The secondary latch is not transparent to the input from the primary latch during this state. The primary latch is available to be written only while clk=0 or nc1=1. During this phase, the secondary side retains the data written in a previous write cycle by a cross-coupled inverter at nodes nk16 and nk15.

In FIGS. 2C and 2E, with clk=1, the data is written to the secondary stage and thus the output. In this state, the primary node is not available to be written from the “d” node and the primary nodes nk13 and nk14 are short circuited to nk16 and nk15, respectively. In particular, nk13 is short-circuited to nk16 via P13, nk13a, P10 and node 292, and nk14 is short-circuited to nk15 via P11 and node 291. During this phase, the path to ground is isolated from the secondary node in which “1” is being written. This prevents a loss of dynamic power due to crowbar current that is seen in a standard flip-flop or latch write cycle. This is a secondary write cycle, in which the clock-to-Q (output) delay is determined.

Generally, the primary latch reduces the number of clock transistors compared to a standard flip-flop while also retaining the data during the high phase of the clock (clk=1) through the use of nodes with floating voltages which block a ground path which can occur, e.g., via leaky transistors.

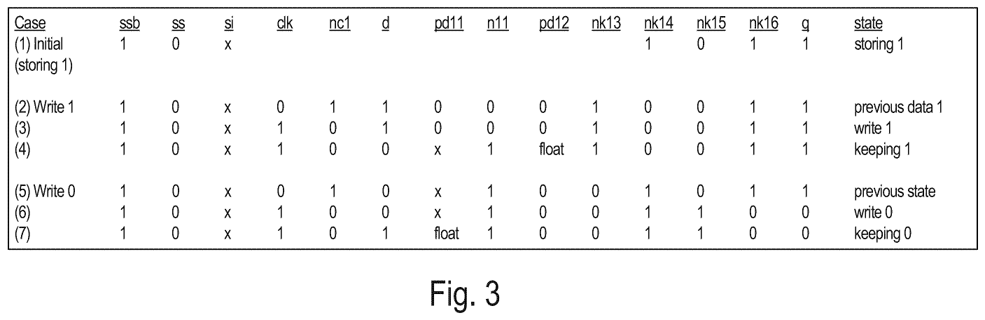

FIG. 3 depicts an example table explaining the operations in FIGS. 2B-2E, in accordance with various embodiments. In the operations, a 0 or 1 value is associated with the different nodes of the flip-flop 200. “x” denotes a don't care value. Row (1) is for the state of storing a 1. Rows (2)-(4) are for writing a 1. Row (2) is for state where the previous data is 1. Row (3) is for the state of writing a 1. Row (4) is for the state of keeping the 1. Rows (5)-(7) are for writing a 0. Row (5) is for the previous state. Row (6) is for the state of writing a 0. Row (7) is for the case of a previous state.

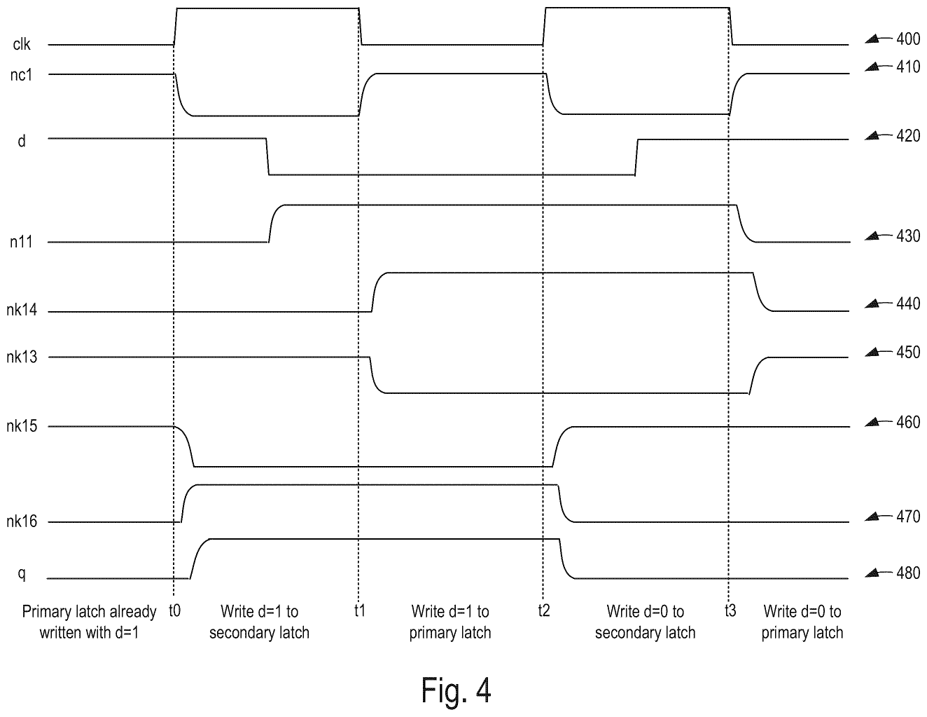

FIG. 4 depicts example waveforms consistent with the flip-flop circuit 200 of FIG. 2A-2E, in accordance with various embodiments. The waveforms depicts a voltage versus time, where time points t0-t4 are noted. Plots 400, 410, 420, 430, 440, 450, 460, 470 and 480 denote clk, nc1, d, n11, nk14, nk13, nk15, nk16 and q, respectively. In this example, before to, the primary latch is already written with d=1. This is consistent with nk13=1 since this is the node in the primary latch that stores d.

At t0, d=1 is written to the secondary latch. This is consistent with nk16 transitioning to 1 since this is the node in the secondary latch that stores d. In this example, a write operation of the secondary latch is initiated by an increasing edge of the received clock signal clk.

At t1, d=0 is written to the primary latch. This is consistent with nk13 transitioning to 0. In this example, a write operation of the primary latch is initiated by a decreasing edge of clk.

At t2, d=0 is written to the secondary latch. This is consistent with nk16 transitioning to 0.

At t3, d=1 is written to the primary latch. This is consistent with nk13 transitioning to 1.

The plots also indicate how nk14 stores the inverse data of nk13, and nk15 stores the inverse data of nk16.

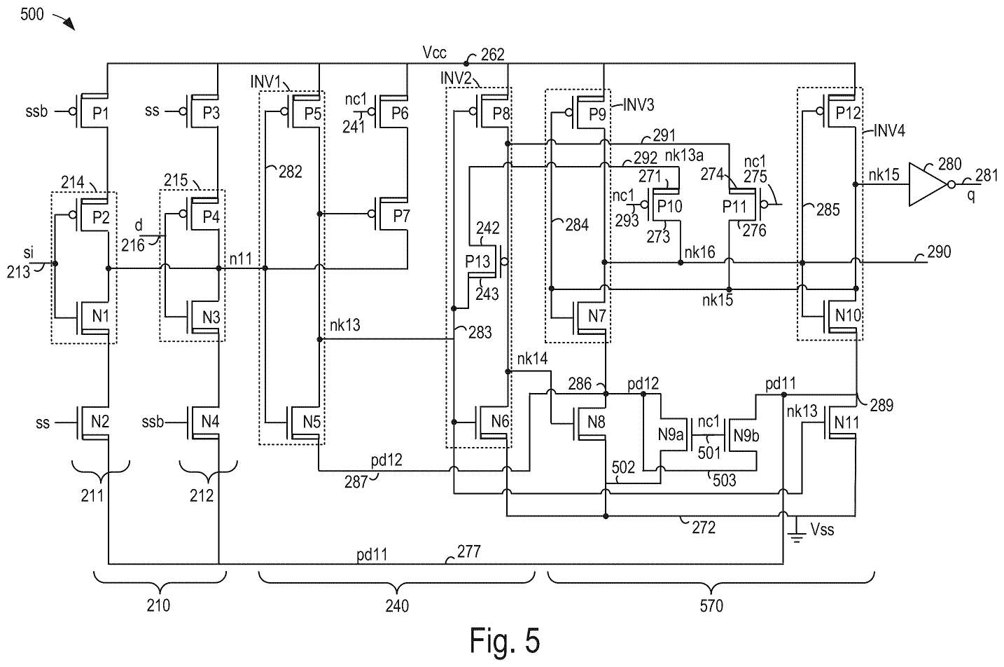

FIG. 5 depicts an example flip-flop circuit 500 similar to the flip-flop circuit 200 of FIG. 2A but with transistors N9a and N9b instead of N9 in the secondary latch 570, in accordance with various embodiments. The flip-flop 500 includes the input multiplexer 210, the primary latch 240 and a secondary latch 570. In this example, N9a and N9b are nMOSFETs which have their control gates coupled to one another to receive nc1 at a node 501. When nc1 is high, N9a and N9b are on. N9a couples pd12, at a drain of N9a, to a node 502 and to the ground node 272. N9b couples pd11, at a drain of N9b, to pd12 at a source of N9b, via a path 503. pd12 and pd11 can be grounded when N8 or N11, respectively, are on. N9a and N9b provide a more robust design by providing two transistors which can drive a ground voltage instead of the one transistor N9 in FIG. 2A.

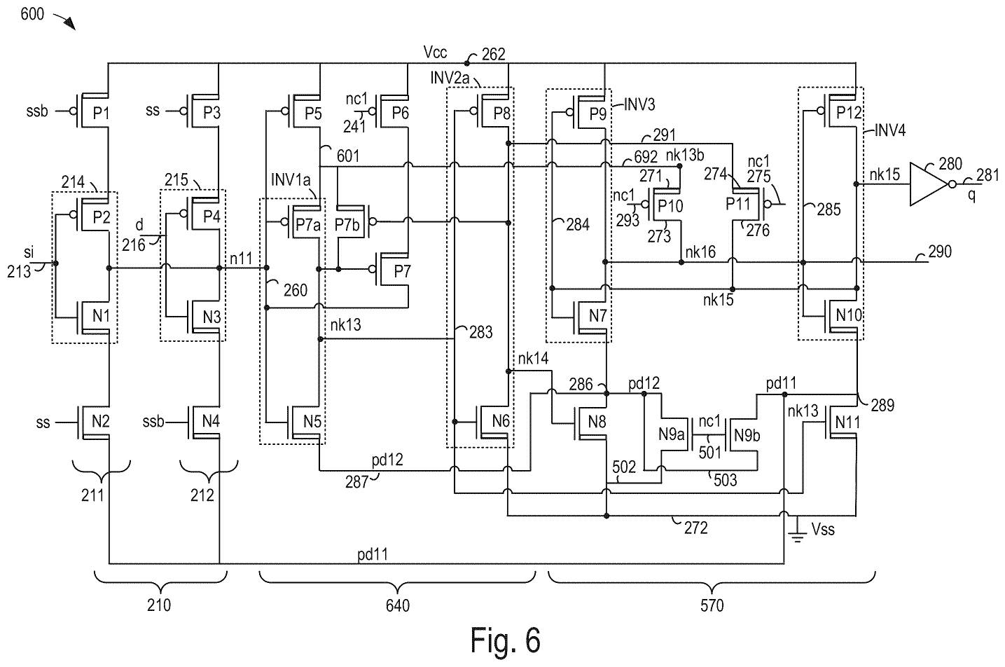

FIG. 6 depicts an example flip-flop circuit 600 similar to the flip-flop circuit 500 of FIG. 5 but with transistors P7a and P7b instead of P13 in the primary latch 640, in accordance with various embodiments. The flip-flop 600 includes the input multiplexer 210, a primary stage 640 and the secondary stage 570. The primary stage 640 includes first and second cross-coupled inverters INV1a and INV2a, respectively. INV1a includes Pa and N5 having their control gates coupled to node 216. P5 is a stacked or pull up transistor coupled between INV1a and the power supply node 262 at Vcc. INV2a includes P8 and N6 having their control gates coupled to nodes nk13 and 283. Node 260 is also coupled to the control gate of P5. The output of INV1a is at nodes nk13 and 283. A node 601 between P5 and P7a is coupled to nk13b and node 692. Additionally, P7b is coupled between nodes 601 and nk13, and has its control gate coupled to nk14, which is the output of INV2a.

P7a and P7b replace P13, and nk13b replaces nk13a, in the above-mentioned flip-flops. Using two transistors in parallel instead of one transistor performs the same function but provides the advantage of a symmetric design. This means better symmetry between the rise and fall time at the output node 281.

The dual transistors N9a and N9b are depicted here but the single transistor N9 could be used alternatively.

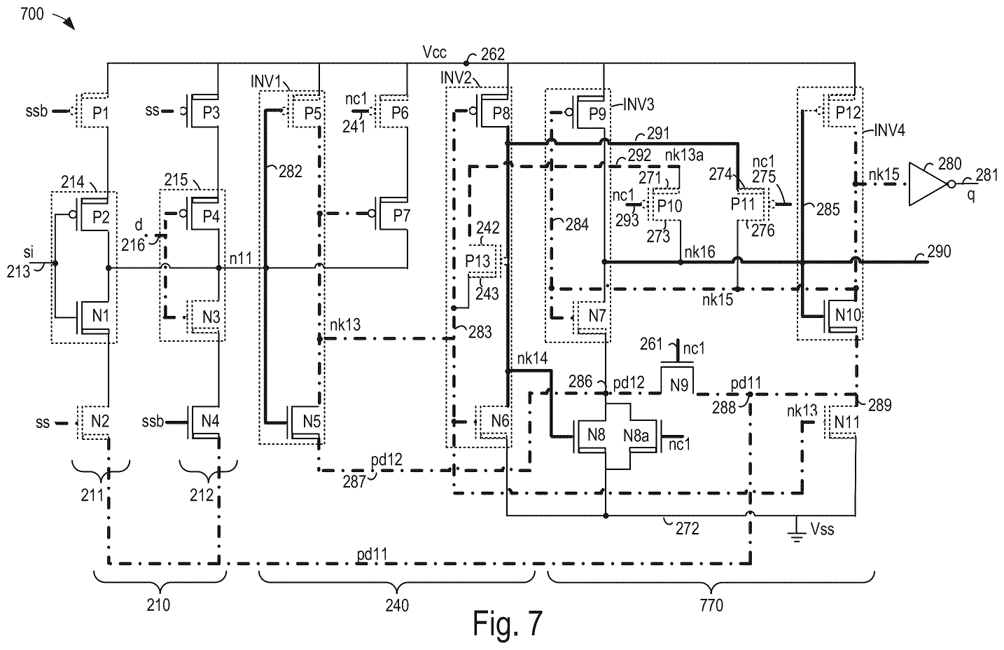

FIG. 7 depicts an example flip-flop circuit 700 similar to the flip-flop circuit 200 of FIG. 2B but with a transistor N8a added in the secondary latch 770, in accordance with various embodiments. The configuration is shown when writing data=0 to the primary latch 240, with CLK=0, as an example. Instead of the single N8 transistor, an additional transistor N8a is provided in parallel with N8. N8a is a clocked transistor which receives nc1 at its control gate while N8 receives nk14 at its control gate, as discussed previously.

This design modification can improve the performance of a flip-flop with a high sigma variation. The design modification include a partial AND-OR-Inverter (AOI) based data retention scheme during the clock low phase at the input. The partial AOI based design avoids a bridge-based clock sharing the Vss, thus avoiding loss of Vss due to inverter delay during switching between ground nodes.

The single transistor N9 is depicted here but the dual transistors N9a and N9b could be used alternatively.

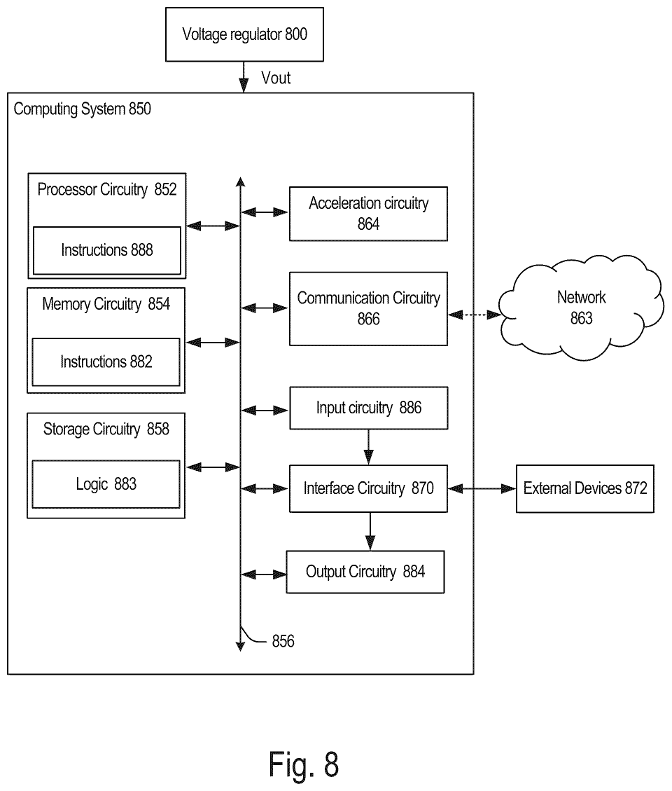

FIG. 8 illustrates an example of components that may be present in a computing system 850 for implementing the techniques (e.g., operations, processes, methods, and methodologies) described herein. The flip-flops described herein can be in any of the components depicted. The flip-flops described herein can be in any sequential logic circuit.

The voltage regulator 1700 may provide a voltage Vout to one or more of the components of the computing system 1750. The memory circuitry 1754 may store instructions and the processor circuitry 1752 may execute the instructions to perform the functions described herein.

The computing system 1750 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 1750, or as components otherwise incorporated within a chassis of a larger system. For one embodiment, at least one processor 1752 may be packaged together with computational logic 1782 and configured to practice aspects of various example embodiments described herein to form a System in Package (SiP) or a System on Chip (SoC).

The system 1750 includes processor circuitry in the form of one or more processors 1752. The processor circuitry 1752 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 1752 may include one or more hardware accelerators (e.g., same or similar to acceleration circuitry 1764), which may be microprocessors, programmable processing devices (e.g., FPGA, ASIC, etc.), or the like. The one or more accelerators may include, for example, computer vision and/or deep learning accelerators. In some implementations, the processor circuitry 1752 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 1752 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 1752 may be coupled with or may include memory/storage and may be configured to execute instructions stored in the memory/storage to enable various applications or operating systems to run on the platform 1750. The processors (or cores) 1752 is configured to operate application software to provide a specific service to a user of the platform 1750. In some embodiments, the processor(s) 1752 may be a special-purpose processor(s)/controller(s) configured (or configurable) to operate according to the various embodiments herein.

As examples, the processor(s) 1752 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 1752 may be a part of a system on a chip (SoC), System-in-Package (SiP), a multi-chip package (MCP), and/or the like, in which the processor(s) 1752 and other components are formed into a single integrated circuit, or a single package, such as the Edison™ or Galileo™ SoC boards from Intel® Corporation. Other examples of the processor(s) 1752 are mentioned elsewhere in the present disclosure.

The system 1750 may include or be coupled to acceleration circuitry 1764, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 1764 may comprise logic blocks or logic fabric and other interconnected resources that may be programmed (configured) to perform various functions, such as the procedures, methods, functions, etc. of the various embodiments discussed herein. In such implementations, the acceleration circuitry 1764 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 1752 and/or acceleration circuitry 1764 may include hardware elements specifically tailored for machine learning and/or artificial intelligence (AI) functionality. In these implementations, the processor circuitry 1752 and/or acceleration circuitry 1764 may be, or may include, an AI engine chip that can run many different kinds of AI instruction sets once loaded with the appropriate weightings and training code. Additionally or alternatively, the processor circuitry 1752 and/or acceleration circuitry 1764 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPS™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 1752 and/or acceleration circuitry 1764 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin 1770 provided by Huawei®, and/or the like. In some hardware-based implementations, individual subsystems of system 1750 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 1750 also includes system memory 1754. Any number of memory devices may be used to provide for a given amount of system memory. As examples, the memory 1754 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 1754 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 1754 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 1758 provides persistent storage of information such as data, applications, operating systems and so forth. In an example, the storage 1758 may be implemented via a solid-state disk drive (SSDD) and/or high-speed electrically erasable memory (commonly referred to as “flash memory”). Other devices that may be used for the storage 1758 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 1754 and/or storage circuitry 1758 may also incorporate three-dimensional (3D) cross-point (XPOINT) memories from Intel® and Micron®.

The memory circuitry 1754 and/or storage circuitry 1758 is/are configured to store computational logic 1783 in the form of software, firmware, microcode, or hardware-level instructions to implement the techniques described herein. The computational logic 1783 may be employed to store working copies and/or permanent copies of programming instructions, or data to create the programming instructions, for the operation of various components of system 1750 (e.g., drivers, libraries, application programming interfaces (APIs), etc.), an operating system of system 1750, one or more applications, and/or for carrying out the embodiments discussed herein. The computational logic 1783 may be stored or loaded into memory circuitry 1754 as instructions 1782, or data to create the instructions 1782, which are then accessed for execution by the processor circuitry 1752 to carry out the functions described herein. The processor circuitry 1752 and/or the acceleration circuitry 1764 accesses the memory circuitry 1754 and/or the storage circuitry 1758 over the interconnect (IX) 1756. The instructions 1782 direct the processor circuitry 1752 to perform a specific sequence or flow of actions, for example, as described with respect to flowchart(s) and block diagram(s) of operations and functionality depicted previously. The various elements may be implemented by assembler instructions supported by processor circuitry 1752 or high-level languages that may be compiled into instructions 1488, or data to create the instructions 1488, to be executed by the processor circuitry 1452. The permanent copy of the programming instructions may be placed into persistent storage devices of storage circuitry 1458 in the factory or in the field through, for example, a distribution medium (not shown), through a communication interface (e.g., from a distribution server (not shown)), over-the-air (OTA), or any combination thereof.

The IX 1756 couples the processor 1752 to communication circuitry 1766 for communications with other devices, such as a remote server (not shown) and the like. The communication circuitry 1766 is a hardware element, or collection of hardware elements, used to communicate over one or more networks 1763 and/or with other devices. In one example, communication circuitry 1766 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 1766 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 1756 also couples the processor 1752 to interface circuitry 1770 that is used to connect system 1750 with one or more external devices 1772. The external devices 1772 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 1750, which are referred to as input circuitry 1786 and output circuitry 1784. The input circuitry 1786 and output circuitry 1784 include one or more user interfaces designed to enable user interaction with the platform 1750 and/or peripheral component interfaces designed to enable peripheral component interaction with the platform 1750. Input circuitry 1786 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 1784 may be included to show information or otherwise convey information, such as sensor readings, actuator position(s), or other like information. Data and/or graphics may be displayed on one or more user interface components of the output circuitry 1784. Output circuitry 1784 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 1450. The output circuitry 1484 may also include speakers and/or other audio emitting devices, printer(s), and/or the like. Additionally or alternatively, sensor(s) may be used as the input circuitry 1484 (e.g., an image capture device, motion capture device, or the like) and one or more actuators may be used as the output device circuitry 1784 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 1750 may communicate over the IX 1756. The IX 1756 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 1756 may be a proprietary bus, for example, used in a SoC based system.

The number, capability, and/or capacity of the elements of system 1750 may vary, depending on whether computing system 1750 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 1450 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Some non-limiting examples of various embodiments are presented below.

Example 1 includes an apparatus, comprising: a primary latch (240) comprising a first inverter (INV1) and a second inverter (INV2), wherein an output of the first inverter is a first storage node (nk13), an output of the second inverter is a second storage node (nk14), and the primary latch comprises a first transistor (P13) having a source coupled to the first storage node and a gate coupled to the second storage node; and a secondary latch (270) coupled to the primary latch, wherein the secondary latch comprises a third inverter (INV3) and a fourth inverter (INV4), an output of the third inverter is a third storage node (nk16), an output of the fourth inverter is a fourth storage node (nk15), and the secondary latch comprises a first clocked transistor (P10) having a source coupled to a drain of the first transistor (P13) and a drain coupled to the third storage node (nk16), and a second clocked transistor (P11) having a source coupled to the second storage node and a drain coupled to the fourth storage node (nk15).

Example 2 includes the apparatus of Example 1, further comprising: a first grounding transistor (N8) coupled to the third inverter and to a ground node; a second grounding transistor (N11) coupled to the fourth inverter and to the ground node; and a clocked bridge transistor (N9) coupled to a node (pd12) between the third inverter and the first grounding transistor and to node (pd11) between the fourth inverter and the second grounding transistor.

Example 3 includes the apparatus of Example 2, further comprising: a multiplexer having an output node (n11), wherein the output node is an input node of the first inverter; and a pulldown transistor (N4) of the multiplexer coupled to the node (pd11) between the fourth inverter and the second grounding transistor.

Example 4 includes the apparatus of any one of claims 1-3, further comprising: a first grounding transistor (N8) coupled to the third inverter and to a ground node; a second grounding transistor (N11) coupled to the fourth inverter and to the ground node; a first clocked pulldown transistor (N9a) coupled to the ground node and to a node (pd12) between the third inverter and the first grounding transistor; and a second clocked pulldown transistor (N9b) coupled to the node (pd12) between the third inverter and the first grounding transistor and to a node (pd11) between the fourth inverter and the second grounding transistor (N11).

Example 5 includes the apparatus of Example 4, further comprising: a multiplexer having an output node (n11), wherein the output node is an input node of the first inverter; and a pulldown transistor (N4) of the multiplexer coupled to the node (pd11) between the fourth inverter and the second grounding transistor (N11).

Example 6 includes the apparatus of Example 4 or 5, wherein a control gate of the first grounding transistor is coupled to the second storage node (nk14).

Example 7 includes the apparatus of any one of claims 4-6, wherein the first inverter is coupled to the node (pd12) between the third inverter and the first grounding transistor (N8).

Example 8 includes the apparatus of any one of claims 1-7, further comprising a clocked pull up transistor (P6) coupled to a power supply and to an unclocked transistor (P7), wherein a control gate of the unclocked transistor is coupled to the first storage node (nk13) and a drain of the unclocked transistor is coupled to an input node (n11) of the first inverter.

Example 9 includes the apparatus of any one of claims 1-8, wherein: in a write operation of the primary latch, the first storage node (nk13) is to store a data bit at an input node (n11) of the first inverter and the second storage node (nk14) is to store an inverse of the data bit; and in a write operation of the secondary latch, the third storage node (nk16) is to store the data bit and the fourth storage node (nk15) is to store the inverse of the data bit. Example 10 includes the apparatus of any one of claims 1-9, further comprising an inverter to invert a received clock signal to an inverted clock signal, wherein: a write operation of the primary latch is initiated by a decreasing edge of the received clock signal; a write operation of the secondary latch is initiated by an increasing edge of the received clock signal; and the first clocked transistor (P10) and the second clocked transistor (P11) have control gates coupled to the inverted clock signal.

Example 11 includes the apparatus of any one of claims 1-10, further comprising a sequential logic circuit in which the primary latch and the secondary latch are provided in a flip-flop, wherein the flip-flop is provided in at least one of an integrated circuit, a System on Chip, a System in Package or a computing device, and the computing device comprises at least one of a voltage regulator, processor circuitry, a memory circuitry, a storage circuitry, an acceleration circuitry, a communication circuitry, an input circuitry, an output circuitry, an interface circuitry or an external device.

Example 12 includes an apparatus, comprising: a primary latch comprising a first inverter (INV1a) and a second inverter (INV2a), wherein: an output of the first inverter is a first storage node (nk13); an output of the second inverter is a second storage node (nk14); and a pull up transistor (P5) coupled to the first inverter and to a power supply node (262); and a secondary latch coupled to the primary latch, wherein: the secondary latch comprises a third inverter (INV3) and a fourth inverter (INV4); an output of the third inverter is a third storage node (nk16); an output of the fourth inverter is a fourth storage node (nk15); the secondary latch comprises a first clocked transistor (P10) coupled to a node (nk13a) between the first inverter and the pull up transistor (P5); the first clocked transistor (P10) is coupled to the third storage node (nk16); and secondary latch comprises a second clocked transistor (P11) coupled to the second storage node (nk14) and to the fourth storage node (nk15).

Example 13 includes the apparatus of Example 12, wherein the first inverter comprises a p-type transistor (P7a) in series with an n-type transistor (N5), Example X includes the apparatus further comprising: an additional p-type transistor (P7b) in parallel with the p-type transistor of the first inverter, wherein a gate of the additional p-type transistor is coupled to the second storage node (nk14); and a clocked pull up transistor (P6) coupled to the power supply node (262) and to an unclocked transistor (P7), wherein a drain of the additional p-type transistor (P7b) and a drain of the p-type transistor (P7a) of the first inverter are coupled to the first storage node (nk13) and to a gate of the unclocked transistor (P7), and a drain of the unclocked transistor (P7) is coupled to an input node (n11) of the first inverter.

Example 14 includes the apparatus of Example 12 or 13, further comprising: a first grounding transistor (N8) coupled to the third inverter and to a ground node; a second grounding transistor (N11) coupled to the fourth inverter and to the ground node; a first clocked pulldown transistor (N9a) coupled to the ground node and to a node (pd12) between the third inverter and the first grounding transistor (N8); and a second clocked pulldown transistor (N9b) coupled to the node (pd12) between the third inverter and the first grounding transistor and to a node (pd11) between the fourth inverter and the second grounding transistor (N11).

Example 15 includes the apparatus of any one of claims 12-14, further comprising an inverter (191) to invert a received clock signal to an inverted clock signal, wherein the first clocked transistor (P10) and the second clocked transistor (P11) have control gates coupled to the inverted clock signal.

Example 16 includes the apparatus of any one of claims 12-15, further comprising: a first grounding transistor (N8) coupled to the third inverter and to a ground node; a second grounding transistor (N11) coupled to the fourth inverter and to the ground node; and a clocked bridge transistor (N9) coupled to a node (pd12) between the third inverter and the first grounding transistor and to node (pd11) between the fourth inverter and the second grounding transistor.

Example 17 includes the apparatus of Example 16, further comprising an inverter (191) to invert a received clock signal to an inverted clock signal, wherein the clocked bridge transistor (N9) has a control gate (261) coupled to the inverted clock signal.

Example 18 includes an apparatus, comprising: a primary latch comprising a first inverter (INV1) and a second inverter (INV2), wherein an output of the first inverter is a first storage node (nk13), an output of the second inverter is a second storage node (nk14); a multiplexer having an output node (n11), wherein the output node is an input node of the first inverter; a pulldown transistor (N4) of the multiplexer; and a secondary latch coupled to the primary latch, wherein: the secondary latch comprises a third inverter (INV3) and a fourth inverter (INV4); an output of the third inverter is a third storage node (nk16); an output of the fourth inverter is a fourth storage node (nk15); a grounding transistor (N11) coupled to the fourth inverter and to a ground node; the pulldown transistor (N4) is coupled by a path (277) to a node (288) between the fourth inverter and the grounding transistor (N11); and a voltage of the path is to float during a write operation of the secondary latch to maintain data at the output node (n11).

Example 19 includes the apparatus of Example 18, wherein: the fourth inverter comprises a p-type transistor (P12) and an n-type transistor (N10); the n-type transistor is between the p-type transistor and the grounding transistor (N11); and the n-type transistor and the grounding transistor (N11) are turned off to float the voltage of the path.

Example 20 includes the apparatus of Example 18 or 19, further comprising another grounding transistor (N8) coupled to the third inverter and to a ground node, wherein: the first inverter is coupled by a path (287) to a node (286) between the third inverter and the another grounding transistor; (N8) and a voltage of the path (287) is to float during a write operation of the secondary latch to maintain data at the first storage node (nk13).

Example 21 includes a method, comprising: writing a 0 data bit to first storage node and a 1 data bit to a second storage node, in a primary latch of a flip-flop; and writing the 0 data bit from the first storage node to the third storage node and writing the 1 data bit from the second storage node to a fourth storage node, in a secondary latch of the flip-flop, wherein: the primary latch (240) comprises a first inverter (INV1) and a second inverter (INV2); an output of the first inverter is the first storage node (nk13); an output of the second inverter is the second storage node (nk14); the primary latch comprises a first transistor (P13) having a source coupled to the first storage node and a gate coupled to the second storage node; the secondary latch comprises a third inverter (INV3) and a fourth inverter (INV4); an output of the third inverter is the third storage node (nk16); an output of the fourth inverter is the fourth storage node (nk15); and the secondary latch comprises a first clocked transistor (P10) having a source coupled to a drain of the first transistor (P13) and a drain coupled to the third storage node (nk16), and a second clocked transistor (P11) having a source coupled to the second storage node and a drain coupled to the fourth storage node (nk15).

Example 22 includes the method of Example 21, further comprising floating a voltage of a path between the first clocked transistor and the first transistor when writing the 0 data bit to the first storage node.

Example 23 includes the method of Example 21 or 22, wherein a grounding transistor (N11) is coupled to the fourth inverter and to a ground node, a pulldown transistor (N4) is coupled by a path (277) to a node (288) between the fourth inverter and the grounding transistor (N11), and the method further comprises floating a voltage of the path when writing the 0 data bit to the third storage node, to maintain data at the first storage node (nk13).

Example 24 includes the method of any one of Examples 21-23, wherein another grounding transistor (N8) is coupled to the third inverter and to a ground node, the first inverter is coupled by a path (287) to a node (286) between the third inverter and the another grounding transistor (N8), and the method further comprises floating a voltage of the path when writing a 1 data bit to the third storage node, to maintain data at the first storage node (nk13).

Example 25 includes a non-transitory machine-readable storage including machine-readable instructions that, when executed, cause a processor or other circuit or computing device to implement the method of any one of Examples 21-24.

Example 26 includes a computer program comprising instructions which, when the program is executed by a computer, cause the computer to carry out the method of any one of Examples 21-24.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus, comprising:
a primary latch comprising a first inverter and a second inverter, wherein an output of the first inverter is a first storage node, an output of the second inverter is a second storage node, and the primary latch comprises a first transistor having a source coupled to the first storage node and a gate coupled to the second storage node; and
a secondary latch coupled to the primary latch, wherein the secondary latch comprises a third inverter and a fourth inverter, an output of the third inverter is a third storage node, an output of the fourth inverter is a fourth storage node, and the secondary latch comprises a first clocked transistor having a source coupled to a drain of the first transistor and a drain coupled to the third storage node, and a second clocked transistor having a source coupled to the second storage node and a drain coupled to the fourth storage node.

2. The apparatus of claim 1, further comprising:
a first grounding transistor coupled to the third inverter and to a ground node;
a second grounding transistor coupled to the fourth inverter and to the ground node; and
a clocked bridge transistor coupled to a node between the third inverter and the first grounding transistor and to node between the fourth inverter and the second grounding transistor.

3. The apparatus of claim 2, further comprising:
a multiplexer having an output node, wherein the output node is an input node of the first inverter; and
a pulldown transistor of the multiplexer coupled to the node between the fourth inverter and the second grounding transistor.

4. The apparatus of claim 1, further comprising:
a first grounding transistor coupled to the third inverter and to a ground node;
a second grounding transistor coupled to the fourth inverter and to the ground node;
a first clocked pulldown transistor coupled to the ground node and to a node between the third inverter and the first grounding transistor; and
a second clocked pulldown transistor coupled to the node between the third inverter and the first grounding transistor and to a node between the fourth inverter and the second grounding transistor.

5. The apparatus of claim 4, further comprising:
a multiplexer having an output node, wherein the output node is an input node of the first inverter; and
a pulldown transistor of the multiplexer coupled to the node between the fourth inverter and the second grounding transistor.

6. The apparatus of claim 4, wherein a control gate of the first grounding transistor is coupled to the second storage node.

7. The apparatus of claim 4, wherein the first inverter is coupled to the node between the third inverter and the first grounding transistor.

8. The apparatus of claim 1, further comprising a clocked pull up transistor coupled to a power supply and to an unclocked transistor, wherein a control gate of the unclocked transistor is coupled to the first storage node and a drain of the unclocked transistor is coupled to an input node of the first inverter.

9. The apparatus of claim 1, wherein:
in a write operation of the primary latch, the first storage node is to store a data bit at an input node of the first inverter and the second storage node is to store an inverse of the data bit; and
in a write operation of the secondary latch, the third storage node is to store the data bit and the fourth storage node is to store the inverse of the data bit.

10. The apparatus of claim 1, further comprising an inverter to invert a received clock signal to an inverted clock signal, wherein:
a write operation of the primary latch is initiated by a decreasing edge of the received clock signal;
a write operation of the secondary latch is initiated by an increasing edge of the received clock signal; and
the first clocked transistor and the second clocked transistor have control gates coupled to the inverted clock signal.

11. The apparatus of claim 1, further comprising a sequential logic circuit in which the primary latch and the secondary latch are provided in a flip-flop, wherein the flip-flop is provided in at least one of an integrated circuit, a System on Chip, a System in Package or a computing device, and the computing device comprises at least one of a voltage regulator, processor circuitry, a memory circuitry, a storage circuitry, an acceleration circuitry, a communication circuitry, an input circuitry, an output circuitry, an interface circuitry or an external device.

12. An apparatus, comprising:
a primary latch comprising a first inverter and a second inverter, wherein:
an output of the first inverter is a first storage node;
an output of the second inverter is a second storage node; and
a pull up transistor coupled to the first inverter and to a power supply node; and
a secondary latch coupled to the primary latch, wherein:
the secondary latch comprises a third inverter and a fourth inverter;
an output of the third inverter is a third storage node;
an output of the fourth inverter is a fourth storage node;
the secondary latch comprises a first clocked transistor coupled to a node between the first inverter and the pull up transistor;
the first clocked transistor is coupled to the third storage node; and
the secondary latch comprises a second clocked transistor coupled to the second storage node and to the fourth storage node.

13. The apparatus of claim 12, wherein the first inverter comprises a p-type transistor in series with an n-type transistor, the apparatus further comprising:
an additional p-type transistor in parallel with the p-type transistor of the first inverter, wherein a gate of the additional p-type transistor is coupled to the second storage node; and
a clocked pull up transistor coupled to the power supply node and to an unclocked transistor, wherein a drain of the additional p-type transistor and a drain of the p-type transistor of the first inverter are coupled to the first storage node and to a gate of the unclocked transistor, and a drain of the unclocked transistor is coupled to an input node of the first inverter.

14. The apparatus of claim 12, further comprising:
a first grounding transistor coupled to the third inverter and to a ground node;
a second grounding transistor coupled to the fourth inverter and to the ground node;
a first clocked pulldown transistor coupled to the ground node and to a node between the third inverter and the first grounding transistor; and
a second clocked pulldown transistor coupled to the node between the third inverter and the first grounding transistor and to a node between the fourth inverter and the second grounding transistor.

15. The apparatus of claim 12, further comprising an inverter to invert a received clock signal to an inverted clock signal, wherein the first clocked transistor and the second clocked transistor have control gates coupled to the inverted clock signal.

16. The apparatus of claim 12, further comprising:
a first grounding transistor coupled to the third inverter and to a ground node;
a second grounding transistor coupled to the fourth inverter and to the ground node; and
a clocked bridge transistor coupled to a node between the third inverter and the first grounding transistor and to node between the fourth inverter and the second grounding transistor.

17. The apparatus of claim 16, further comprising an inverter to invert a received clock signal to an inverted clock signal, wherein the clocked bridge transistor has a control gate coupled to the inverted clock signal.

18. An apparatus, comprising:
a primary latch comprising a first inverter and a second inverter, wherein an output of the first inverter is a first storage node, an output of the second inverter is a second storage node;
a multiplexer having an output node, wherein the output node is an input node of the first inverter;
a pulldown transistor of the multiplexer; and
a secondary latch coupled to the primary latch, wherein:
the secondary latch comprises a third inverter and a fourth inverter;
an output of the third inverter is a third storage node;
an output of the fourth inverter is a fourth storage node;
a grounding transistor coupled to the fourth inverter and to a ground node;
the pulldown transistor is coupled by a path to a node between the fourth inverter and the grounding transistor; and
a voltage of the path is to float during a write operation of the secondary latch to maintain data at the output node.

19. The apparatus of claim 18, wherein:
the fourth inverter comprises a p-type transistor and an n-type transistor;
the n-type transistor is between the p-type transistor and the grounding transistor; and
the n-type transistor and the grounding transistor are turned off to float the voltage of the path.

20. The apparatus of claim 18, further comprising another grounding transistor coupled to the third inverter and to a ground node, wherein:
the first inverter is coupled by a path to a node between the third inverter and the another grounding transistor; and
a voltage of the path is to float during a write operation of the secondary latch to maintain data at the first storage node.
